(19) United States
(12) Patent Application Publication
(10) Pub. No.: US 2011/0014442 A1
(43) Pub. Date: Jan. 20, 2011

(54) POLYMERIC BASED LENS COMPRISING HARDENING LAYER, AN INTERFERENTIAL MULTI-LAYER AND A HARD LAYER SANDWICHED BETWEEN BOTH, AND CORRESPONDING MANUFACTURING METHOD

(76) Inventors: Ricardo Fernández Serrano, Madrid (ES); Eva Gutiérrez Berasategui, Vizcaya (ES); Antoni Vilajoana I Mas, Barcelona (ES); Juan Carlos Dürsteler Lòpez, Barcelona (ES)

Correspondence Address: STAAS & HALSEY LLP, SUITE 700, 1201 NEW YORK AVENUE, N.W., WASHINGTON, DC, 20005, US

(21) Appl. No.: 12/735,747

(22) PCT Filed: Dec. 15, 2008
(86) PCT No.: PCT/EP2008/010647

§ 371 Date: Sep. 24, 2010

(30) Foreign Application Priority Data
Feb. 14, 2008 (ES) 200800387

(51) Int. Cl. G02B 1/10; C23C 14/34; C23C 14/06; G02C 7/02; G02B 1/11

(52) U.S. Cl. 428/216; 427/162; 427/488; 204/192.26

(57) ABSTRACT

Polymeric based lens having a hardening layer, an interferential multi-layer and a hard layer sandwiched between both, and corresponding manufacturing method. The hardening layer is over 500 nm thick. The interferential multi-layer is made up of a plurality of sub layers each of which is less than 250 nm thick. The hard layer is over 300 nm thick. The lens can also have a flexible layer, obtained by polymerizing organometallic monomers by means of PECVD and/or sputtering, arranged between the hardening layer and the hard layer. The manufacturing method includes a high vacuum activation phase of the hardening layer surface, before the hard layer formation stage.

### FIELD OF THE INVENTION

The invention relates to polymeric based lenses that are highly abrasion resistant, which usually comprise a hardening layer and an interferential multi-layer, where the hardening layer is at least 500 nm (nanometres) thick and the interferential multi-layer is made up of a plurality of sub layers where each of said sub layers is less than 250 nm thick. The invention also relates to some manufacturing methods of these lenses.

### STATE OF THE ART

Lens coating is well known, and in particular ophthalmic lenses of a polymeric or organic nature, with hardening layers to improve the abrasion resistance thereof. This coating method is carried out because the scratch resistance of this type of polymeric lenses is much less than that of mineral lenses. This hardening coating (lacquer) is usually applied by dipping in a (poly)siloxane, acrylic, methacrylic or polyurethane bath and subsequent hardening in an oven at temperatures between 100° C. and 130° C. Via this method hardening layers of between 1 micron and 3 microns are obtained. Another possible technique for carrying out the hardening coating is by applying lacquers using the spinning technique with mechanical characteristics that are similar to the above but with a production process that only coats one lens surface in each stage.

It is also known to cover lenses with a stack of layers that have an anti-reflection (or interferential) function that enables them to reduce the amount of visible light reflected by the lens or with an interferential stack that has a mirror function to increase said reflected light. In order to obtain these results, usually a stack of between 4 and 6 layers is used, each of which is between 10 nm and 150 nm thick. This is usually done using PVD (Physical Vapour Deposition) techniques with an electron gun or thermal evaporation, although other techniques exist such as Plasma enhanced Chemical Vapour Deposition (PeCVD) or Sputtering.

The mechanical properties of these layers deposited by high vacuum afford the lacquered polymeric organic unit greater hardness and increased scratch and abrasion resistance. This abrasion resistance measurement is usually made in the industry using the so-called Bayer test by the firm Colts Laboratories, relating to the standard L-11-10-06 operational procedure, comparing the abrasion resistance to that of a CR39 substrate. Thus, a value of BR=10 means that the treated lens is 10 times more resistant to abrasion than the CR39 lens. This test has been used in this invention.

Also a pressure-based test is usually used to measure the abrasion resistance of the lens, called the Steel Wool SW test by the firm Colts Laboratories, relating to the standard L-11-12-08 operational procedure. This test has also been used in this invention, but in a modified way: the time was increased to 10 minutes and the applied load was increased to 6 kg in view of the high abrasion resistance of the lenses.

Document EP 1.655.385, in the name of Satis Vacuum Industries Vertriebs—AG, describes a procedure wherein between the organic substrate and the interferential multi-layer a transition layer is sandwiched, made up of PeCVD and using hexamethyldisiloxane (HMDSO) as the precursor.

Document U.S. Pat. No. 6,596,368, in the name of Essilor International, describes some specific sputtering methods that make it possible to improve the adherence of the interferential multi-layer to the polymeric substrate or to the hardening layer (the lacquer).

Nevertheless, there is still the need to improve the abrasion resistance of polymeric-based lenses and also the need for the various layers of a polymeric based lens, particularly the interferential multi-layers, to adhere as much as possible.

In this description and claims the term “lens” must be understood as any optical system made up of at least one surface and having refraction and/or reflection properties. In other words, any optical system based on refraction phenomena (refraction systems) or reflection phenomena (reflection systems). Those optical systems that combine both effects must also be considered to be lenses, such as for example optical systems with a first refraction surface and a second reflection surface, optical surfaces with semitransparent surfaces, etc.

### DISCLOSURE OF THE INVENTION

The aim of the invention is to overcome these drawbacks. This aim is achieved by means of a lens of the type indicated at the beginning, characterised in that it comprises, in addition, a hard layer sandwiched between said hardening layer and said interferential multi-layer, wherein said hard layer is over 300 nm thick and is made from a material in the group made by: metallic chrome, Cr₂O₃, metallic zirconium, ZrO, ZrO₂, metallic silicon, SiO, SiO₂, metallic titanium, TiO, TiO₂, Ti₃O₅, metallic aluminium, Al₂O₃, metallic tantalum, Ta₂O₅, metallic cerium, CeO₂, metallic hafnium, HfO₂, indium and tin oxide, metallic yttrium, Y₂O₃, magnesium, MgO, carbon, praseodymium, PrO₂, Pr₂O₃, tungsten, WO₃, silicon nitride, and silicon oxynitride.

In fact, by including this hard layer over 300 nm thick makes it possible to improve the unit's mechanical response. This is due to the fact that the unit's mechanical response to nanoindentation tests is that of the interferential multi-layer if the indentation penetration value is less than 10% of the thickness of the interferential multi-layer. If the value of the indentation penetration is greater, then the unit's mechanical response is influenced by the mechanical properties of the lower layers and, eventually, of the actual polymeric substrate. Therefore, the addition of this hard layer which, in fact, can be of the same material as any of the sub layers of the interferential multi-layer, but which is much thicker than any of the sub layers of the interferential multi-layer, makes it possible to noticeably improve the unit's mechanical properties, particularly its abrasion resistance. Therefore, this hard layer is not really playing an interferential role, but rather the role of improving the mechanical properties.

Nevertheless, including this hard layer hinders the adhesion of the interferential multi-layer, which can cause a problem in certain cases, particularly if a very thick hard layer is to be included. Therefore, advantageously the lens has a flexible layer, obtainable by polymerizing organometallic monomers using a PECVD and/or sputtering method, and arranged between said hardening layer and said hard layer. In fact, this flexible layer improves the adhesion of the interferential multi-layer because it makes the unit flexible and accommodates the state of residual stresses introduced with the hard layer and interferential multi-layer. The flexible layer thus obtained has intermediate mechanical properties between the hard layer (and the interferential multi-layer) and the hardening layer. This way, by combining the hard layer with the flexible layer it is possible to select the abrasion resistance value directly by selecting the thickness of the thick layer and flexible layer. The possibility of having processes whereby a wider range of abrasion resistances can be obtained, even tens of times the value of the lacquered lens, according to the lens manufacturing conditions means it is possible to design processes personalised to the needs of each specific application.

A person skilled in the art knows the technique of forming layers by polymerizing organometallic monomers and can recognise when a certain layer is formed using this technique. However, it is complicated to define this type of layers by their physical characteristics, and therefore it is necessary to define them by the way in which they are obtained. However, it must be clear that the flexible layer is advantageous in itself, irrespective of the method that has been used to produce it. Consequently, it must be clear that the term “obtainable” is intended to define what the layer itself is like, irrespective of the method used to obtain it.

Preferably the lens has an adherent layer less than 10 nm thick, sandwiched between said hardening layer and said flexible layer, where said adherent layer is made from material in the group made up of: metallic chrome, Cr₂O₃, metallic zirconium, ZrO, ZrO₂, metallic silicon, SiO, SiO₂, metallic titanium, TiO, TiO₂, Ti₃O₅, metallic aluminium, Al₂O₃, metallic tantalum, Ta₂O₅, metallic cerium, CeO₂, metallic hafnium, HfO₂, indium and tin oxide, metallic yttrium, Y₂O₃, magnesium, MgO, carbon, praseodymium, PrO₂, Pr₂O₃, tungsten, WO₃, silicon nitride, and silicon oxynitride. This way the unit's adherence is improved further.

Advantageously the flexible layer is thicker than the unit made up of the hard layer and the interferential multi-layer. Particularly, it is advantageous that the sum of the thickness of the hard layer plus the thickness of the interferential multi-layer is between 70% and 100% of the thickness of the flexible layer.

A preferable embodiment of a lens according to the invention is obtained by adding a second hard layer and a second flexible layer, sandwiched between the flexible layer and the hard layer, where the second hard layer is between 3 nm and 20 nm thick, and is made from a material in the group made up of: metallic chrome, Cr₂O₃, metallic zirconium, ZrO, ZrO₂, metallic silicon, SiO, SiO₂, metallic titanium, TiO, TiO₂, Ti₃O₅, metallic aluminium, Al₂O₃, metallic tantalum, Ta₂O₅, metallic cerium, CeO₂, metallic hafnium, HfO₂, indium and tin oxide, metallic yttrium, Y₂O₃, magnesium, MgO, carbon, praseodymium, PrO₂, Pr₂O₃, tungsten, WO₃, silicon nitride, and silicon oxynitride.

Advantageously, the interferential multi-layer comprises a plurality of layers or sub layers, preferably between 4 and 6 layers, where each layer is between 10 nm and 220 nm thick.

Preferably the hardening layer is the polysiloxane, acrylic, methacrylic or polyurethane base.

Advantageously the lens according to the invention has a final water-repellent layer, preferably perfluorided and between 5 nm and 40 nm thick.

Preferably the flexible layer and/or the second flexible layer have been made from an organometallic monomer from a family of organometallic monomers in the group of families made up of silicon family, zirconium family, titanium family and tantalum family. Particularly, preferably the flexible layer and/or the second flexible layer have been made from an organometallic monomer from the group made up of: hexamethyldisiloxane (HMDSO), tetraethyl orthosilicate (TEOS), titanium (IV) isopropoxide and tetrakis(dimethylamido)zirconium(IV).

Advantageously the interferential multi-layer and/or the first hard layer and/or the second hard layer has been made from a material from the group made up of: ZrO₂, SiO₂, Si₃N₄ and Ta₂O₅.

A further objective of the invention is a polymeric based lens with an abrasion resistance value greater than 20, measured in BR units according to the Bayer test. In fact, polymeric based lenses with an abrasion resistance value greater than 20 BR are not known, the method described in this invention being the only method capable of obtaining polymeric based lenses with such a high abrasion resistance. Similarly, also an objective of the invention is a polymeric based lens with an abrasion resistance value less than 0.35%, measured in Haze units according to the Steel Wool test, at 6 kg for 10 minutes and with a 0000 mesh. As in the previous case, polymeric based lenses with an abrasion resistance value less than 0.35% Haze are not known in said test conditions.

Furthermore, the aim of the invention is a method for manufacturing a polymeric based lens according to the invention, characterised in that it comprises a stage [a] of forming the hardening layer, a stage [b] of forming the hard layer, a stage [c] for forming the interferential multi-layer, and a stage [a′] of activating the surface of the hardening layer by high vacuum , where stage [a′] takes place before said stage [b]. In fact, performing a process to activate the surface of the hardening layer increases the superficial energy thereof promoting promotes the adherence of the layers deposited subsequently using high vacuum techniques. In view of the chemical nature of the hardening layer, the spectrum of possible chemical treatments that can increase its superficial energy without deteriorating its physical properties and cosmetic appearance is very limited. Nevertheless, the high vacuum processes, such as for example plasma, allow a large number of surface actions that do not deteriorate the physical and chemical properties of the lacquer, or its cosmetic appearance. Moreover, since the process is performed immediately before depositing the following layers using high vacuum techniques, it is not necessary to break the vacuum, which ensures that the surface will not be contaminated with products from the atmosphere once activated.

Preferably the activation stage is performed using a plasma activation process at a frequency greater than 50 kHz. It is particularly advantageous that the plasmas be Ar/O₂/N₂ or mixtures thereof and that the pressure be between 10⁻² and 10⁻⁵ mbar.

Preferably radio frequency impulsed plasma is used and the power applied is between 50 W and 1000 W, producing voltages between 30 V and 500 V.

Advantageously the method comprises a stage [a″] of forming the adherence layer less than 10 nm thick, where stage [a″] takes places after stage [a′], where stage [a″] is carried out by sputtering with an inert gas, preferably argon, in presence of oxygen and with electric power greater than 1500 W, producing voltages over 400 V, preferably electric power greater than 2000 W, producing voltages over 650 V.

Preferably the method comprises stage [a′″] of forming the flexible layer, where stage [a′″] is performed before stage [b], where in stage [a′″] an organometallic monomer is polymerized, where in stage [a′″] a sputtering method and a PeCVD radio frequency method are performed simultaneously, where the sputtering uses inert atmospheric gas, preferably argon, in presence of oxygen and with electric power greater than 1000 W producing voltages over 300 V, preferably with electric power greater than 1500 W producing voltages over 400 V, and in the PeCVD method radio frequency plasma is used, an organometallic monomer is injected, the pressure is between 10⁻² and 10⁻⁵ mbar, and the applied power is between 500 W and 3000 W.

Advantageously stage [b] is a sputtering stage using inert atmospheric gas, preferably argon, in presence of oxygen or nitrogen and with electric power between 500 W and 3000 W producing voltages between 300 V and 800 V.

Preferably stage [c] is a sputtering stage using an inert atmospheric gas, preferably argon, in presence of oxygen or nitrogen alternatively with electric power between 500 W and 3000 W producing voltages between 300 V and 800 V.

Advantageously the method comprises a stage [d] of producing a final water-repellent layer, where stage [d] takes place after stage [c].

### BRIEF DESCRIPTION OF THE DRAWINGS

Other advantages and characteristics of the invention will be appreciated from the following description, which is a non-limiting example of some preferable embodiments of the invention, with reference to the attached drawings, in which:

FIGS. 1 to 5, are a diagrammatic view of a cross section of the layers arranged on the polymeric substrate of the lens, according to various embodiments of the invention.

FIG. 6, is a graph showing the abrasion resistance according to the Bayer test of a lens according to the invention, depending on the thickness of the unit made up of the hard layer and the interferential multi-layer, where the abrasion resistance is indicated in BR units.

FIG. 7, is a graph showing the abrasion resistance according to the Steel wool test of a lens according to the invention, depending on the thickness of the unit made up of the hard layer and the interferential multi-layer, where the abrasion resistance is indicated in Haze units (in %).

### DETAILED DESCRIPTION OF SOME EMBODIMENTS OF THE INVENTION

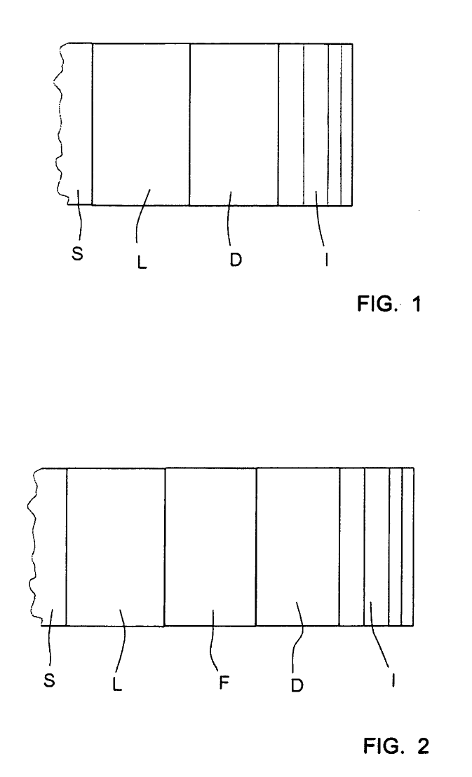

FIG. 1 shows the basic embodiment of the invention. The starting point consists of a polymeric based lens that has a polymeric substrate S on which a hardening layer L has been deposited. A hard layer D has been deposited on hardening layer L, and an interferential layer I has been deposited on hard layer D.

FIG. 2 shows the case wherein a flexible layer F has been added between hardening layer L and hard layer D.

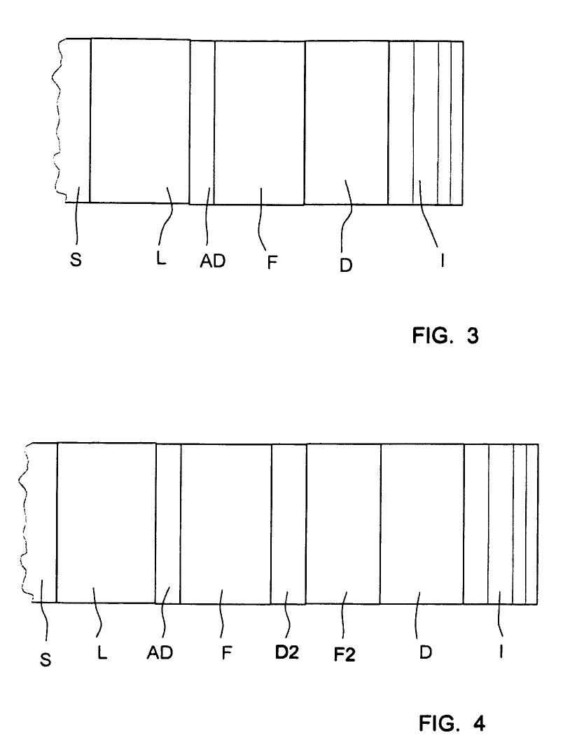

FIG. 3 shows that the structure of the layers also includes an adherence layer AD sandwiched between hardening layer L and flexible layer F

FIG. 4 shows the case wherein the structure of the layers also includes a second is hard layer D2 and a second flexible layer F2 sandwiched between flexible layer F and hard layer D.

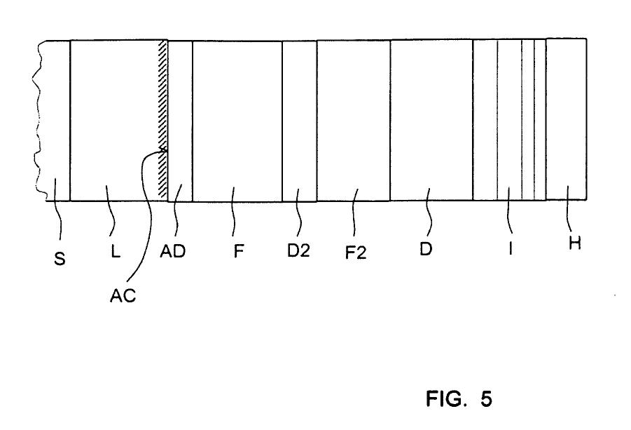

Finally, FIG. 5 shows the layer structure completed with a final water-repellent layer H. Also the activated surface AC of hardening layer L is indicated by stripes.

There is provided below, as an example, a description of a general method for obtaining the organic lens with high abrasion resistance.

The lens unit is covered by dipping or spinning the polysiloxane, acrylic, methacrylic or cured polyurethane lacquer, providing abrasion resistance of at least 4 in the Bayer test, it is washed conventionally to remove any possible superficial defects caused by the presence of dust and other contaminating agents and it is placed in an oven at 80° C. for 2 hours preferably to remove the water adsorbed during the washing process.

Next the activation process of the surface of the lens+lacquer unit is performed, and a stack of layers made up of the following structure, is created inside the high vacuum equipment.

A SiO₂ layer less than 10 nm thick in conditions favouring the adherence of the rest of the structure deposited by high vacuum on the lacquered lens (in other words, with the hardening layer). This layer will be formed by sputtering a silicon or SiO₂ cathode with argon in the presence of oxygen with electric power as high as possible (>1500 W), preferably at 2200 W therefore producing electric voltages of at least 500 V, preferably 700 V.

A flexible layer is deposited over the above-mentioned adherence layer, in which the sputtering and PeCVD radio frequency impulsed plasma processes are combined to polymerize a monomer on the lens surface. To produce this flexible layer, an organometallic volatile silicon precursor, preferably HMDSO is introduced into a chamber during the sputtering process of the silicon or SiO₂ cathode with Ar/He/Ne in presence of oxygen. The entrance flows of the three components, argon, oxygen and HMDSO into the chamber will be between 0 sccm and 50 sccm, at a total pressure of between 10⁻² mbar and 10⁻⁵ mbar and applying electric power between 500 W and 3000 W with resultant voltages of between 300 V and 1000 V.

This flexible layer is divided into two parts by a hard, mineral layer of Si₃N₄ between 3 nm and 20 nm. This is the one previously called the second hard layer. This way, the flexible layer is divided into two, thus forming what was previously called the flexible layer and the second flexible layer.

Then a sputtering layer is preferably deposited (it does not have to be SiO₂) that is more than 300 nm thick. This is the layer that was previously called the hard layer. The deposition conditions will be argon flows between 1 and 20 sccm, in the presence of oxygen or nitrogen between 3 sccm and 50 sccm with electric power of between 500 W and 3000 W producing voltages of between 300 V and 1000 V. The thickness of this layer of SiO₂ has to be such that in addition to the subsequent interferential stack, the total is similar to the thickness of the plasma polymerized flexible layer (in the first approximation between 70% and 100% of the thickness of the flexible layer).

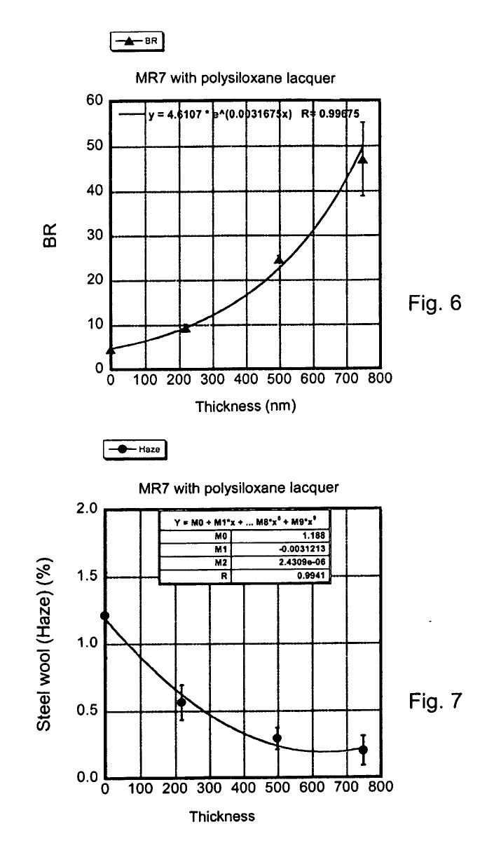

Increasing the thickness of these two layers deposited by PeCVD/sputtering and by sputtering increases the unit's scratch and abrasion resistance from the typical values of BR=5-10 to BR=100 or greater as shown in FIG. 6 as an example.

Then the structure of interferential layers will be applied and deposited by sputtering a silicon cathode with argon, in the presence of oxygen to achieve the anti-reflection or mirror characteristic. The deposition conditions will be argon flows between 1 and 20 sccm, in the alternate presence of oxygen or nitrogen between 3 sccm and 50 sccm with electric power of between 500 W and 3000 W producing voltages of between 300 V and 1000 V.

In all the previous steps where a target or silicon cathode is mentioned that has to be oxydised or nitrided, this can be replaced with an oxide cathode such as for example a (SiO₂, Ta₂O₅, etc.) multi-target. In that case, the contribution of oxygen to obtain the suitable stoicheiometry is less and the process control greater.

Finally using high vacuum electron gun or dipping techniques a layer with a water-repellent function is deposited, preferably a perfluorided layer between 5 and 40 nm that reduces the friction coefficient, which makes it easier to clean the lens.

### Examples

a) Carrying out a process of BR=47 including an interferential multi-layer on a MR7 lens lacquered with (poly)siloxane 2 microns thick.

The lens will preferably be covered by dipping in a (poly)siloxane lacquer cured at 110° C., giving abrasion resistances of BR=4/4.5. This lacquered and cured lens is washed in the presence of ultrasounds with a neutral soap to remove any possible surface defects due to the presence of dust and other contaminating agents, and it is introduced in an oven at 80° C. for at least two hours and not more than 12 hours to remove the water adsorbed by the unit.

Then, using the high vacuum equipment, the activation process of the lacquered lens unit surface is performed and subsequently, without breaking the vacuum at any time until the end of the process, a layer of SiO₂ is deposited by sputtering a pure silicone cathode with 6 sccm of argon in the presence of oxygen (9 sccm) with electric power of 2200 W producing a voltage of about 700 V.

A flexible layer is deposited on this adherence layer, which blends the sputtering and PeCVD radio frequency processes by introducing a volatile silicon precursor, preferably HMDSO into a chamber during the sputtering process (of the silicon cathode using argon in presence of oxygen). The dilutions of the three components, argon, oxygen and HMDSO will be:
40 sccm argon.
12 sccm oxygen.
8 sccm HMDSO.

The total pressure will ideally be 8′0×10⁻⁴ mbar and applying an electrical power of 1750 W and a voltage of about 420 V.

The total thickness of this flexible layer has to be approximately 900 nm. It is possible to spread this layer with the aim of accommodating voltages in various parts of the process.

Subsequently a hard SiO₂ layer approximately 530 nm thick is deposited by sputtering a silicon cathode with argon. The deposition conditions will be an argon flow of 9 sccm, with an oxygen presence of about 12 sccm and with electric power of 1750 W. The resulting voltage will be 550 V.

Then the structure of interferential layers (preferably 4) will be applied to build the interferential multi-layer deposited by sputtering a silicon cathode with argon, in the presence of oxygen/nitrogen alternatively to obtain the anti-reflection characteristic. The deposition conditions will be argon flows of 9 sccm, with an alternated oxygen or nitrogen presence of about 12 sccm and with electric power of 2000 W in all cases. The voltages of the SiO₂ layers will be 550 V and those of the Si₃N₄ layers will be 450 V. The total thickness of the interferential multi-layer is 220 nm.

Owing to the thickness of the 900 nanometre layer polymerized by plasma in the above-mentioned deposition conditions, and the thickness of the 530 nm SiO₂ layer, a unit abrasion resistance value is obtained of about BR=47 on an MR7 substrate.

Finally a layer with a water-repellent function is deposited using the EBPVD, preferably a perfluorided layer of about 15 nm.

Tables:

(The flow values are indicated in sccm)

1.—Conditions of Lacquer Activation Using Plasma by High Vacuum

| | Function | | | | | | | |
|---|---|---|---|---|---|---|---|---|
| | Duration | Power | Voltage | Flow | Flow | Flow | Flow | Pressure |
| | (seg.) | (W) | (V) | [Ar] | [O2] | [N2] | [HMDSO] | (mbar) |
| Activation | 50 | 300 | 200 | 20 | 20 | 0 | 0 | 6.0 10⁻⁴ |

2.—Deposition Conditions of the Adhesion Layer by High Vacuum

| | Function | | | | | | | |
|---|---|---|---|---|---|---|---|---|
| | Thickness | Power | Voltage | Flow | Flow | Flow | Flow | Pressure |
| | (nm) | (W) | (V) | [Ar] | [O2] | [N2] | [HMDSO] | (mbar) |
| Adhesion | 4 | 2200 | 700 | 6 | 9 | 0 | 0 | 2.0 10⁻⁴ |

3.—Deposition Conditions of the Flexible Layer Using PeCVD by High Vacuum

| | Function | | | | | | | |
|---|---|---|---|---|---|---|---|---|
| | Thickness | Power | Voltage | Flow | Flow | Flow | Flow | Pressure |
| | (nm) | (W) | (V) | [Ar] | [O2] | [N2] | [HMDSO] | (mbar) |
| Flexible | 900 | 1750 | 420 | 40 | 12 | 0 | 8 | 8.0 10⁻⁴ |

4.—Deposition Conditions of the Hard SiO₂ Layer more than 300 nm Thick

| | Function | | | | | | | |
|---|---|---|---|---|---|---|---|---|
| | Thickness | Power | Voltage | Flow | Flow | Flow | Flow | Pressure |
| | (nm) | (W) | (V) | [Ar] | [O2] | [N2] | [HMDSO] | (mbar) |
| SiO₂ | 530 | 1750 | 550 | 9 | 12 | 0 | 0 | 2.0 10⁻⁴ |

5.—Deposition Conditions of the Interferential Multi-Layer by High Vacuum

| | Function | | | | | | | |
|---|---|---|---|---|---|---|---|---|
| | Thickness | Power | Voltage | Flow | Flow | Flow | Flow | Pressure |
| | (nm) | (W) | (V) | [Ar] | [O2] | [N2] | [HMDSO] | (mbar) |
| SiO₂ | (2-220) | 1750 | 550 | 9 | 12 | 0 | 0 | 2.0 10⁻⁴ |
| Si₃N₄ | (2-150) | 2000 | 450 | 9 | 0 | 12 | 0 | 2.0 10⁻⁴ |

b) FIGS. 6 and 7 show the abrasion resistance results, according to the Bayer and Steel wool tests at 6 kg for 10 minutes with mesh 0000 respectively, obtained after subjecting an MR7 lens to the following processes:
in both cases, the graph point corresponding to a thickness equivalent to 0, is the abrasion resistance of the lens with just the hardening layer (lacquer layer), and the point corresponding to a thickness equivalent to 220 nm is the abrasion resistance of a lens with a hardening layer and an interferential multi-layer that is 220 nm thick. In other words, both cases are the cases already known in the state of the art.
the two following points now correspond to cases in which a hard layer of variable thickness has been sandwiched, the thickness of the interferential multi-layer remaining constant and equivalent to 220 nm. Specifically, the point of the graph corresponding to a thickness of 750 nm is the case of the lens in example a) above.

c) Performance of a process wherein BR=100 including an interferential multi-layer on a lacquered MR8 lens with a (poly)siloxane lacquer that is 2 microns thick.

Starting with a MR8 lens, and subjecting it to the same method as in example a) above, an abrasion resistance of BR=100 according to the Bayer test is obtained.

1. Polymeric based lens comprising:
a hardening layer and an interferential layer, where said hardening layer is at least 500 nm thick and said interferential multi-layer is made up of a plurality of sub layers where the thickness of each of said sub layers is less than 250 nm; and
a hard layer sandwiched between said hardening layer and said interferential multi-layer, where said hard layer is over 300 nm thick and is made from a material from the group made up of: metallic chrome, Cr₂O₃, metallic zirconium, ZrO, ZrO₂, metallic silicon, SiO, SiO₂, metallic titanium, TiO, TiO₂, Ti₃O₅, metallic aluminium, Al₂O₃, metallic tantalum, Ta₂O₅, metallic cerium, CeO₂, metallic hafnium, HfO₂, indium and tin oxide, metallic yttrium, Y₂O₃, magnesium, MgO, carbon, praseodymium, PrO₂, Pr₂O₃, tungsten, WO₃, silicon nitride, and silicon oxynitride.

2. Lens according to claim 1, further comprising:
a flexible layer obtained by polymerizing organometallic monomers using a PECVD and/or sputtering method, arranged between said hardening layer and said hard layer.

3. Lens according to claim 2, further comprising:
an adherence layer less than 10 nm thick, sandwiched between said hardening layer and said flexible layer, where said adherence layer is made from a material from the group made up of: metallic chrome, Cr₂O₃, metallic zirconium, ZrO, ZrO₂, metallic silicon, SiO, SiO₂, metallic titanium, TiO, TiO₂, Ti₃O₅, metallic aluminium, Al₂O₃, metallic tantalum, Ta₂O₅, metallic cerium, CeO₂, metallic hafnium, HfO₂, indium and tin oxide, metallic yttrium, Y₂O₃, magnesium, MgO, carbon, praseodymium, PrO₂, Pr₂O₃, tungsten, WO₃, silicon nitride, and silicon oxynitride.

4. Lens according to claim 2, wherein a sum of the thickness of said hard layer plus a thickness of said interferential multi-layer is between 70% and 100% a thickness of said flexible layer.

5. Lens according to claim 2, further comprising:
a second hard layer and a second flexible layer, sandwiched between said flexible layer and said hard layer, where said second hard layer is between 3 nm and 20 nm thick and is made from a material from the group made up of: metallic chrome, Cr₂O₃, metallic zirconium, ZrO, ZrO₂, metallic silicon, SiO, SiO₂, metallic titanium, TiO, TiO₂, Ti₃O₅, metallic aluminium, Al₂O₃, metallic tantalum, Ta₂O₅, metallic cerium, CeO₂, metallic hafnium, HfO₂, indium and tin oxide, metallic yttrium, Y₂O₃, magnesium, MgO, carbon, praseodymium, PrO₂, Pr₂O₃, tungsten, WO₃, silicon nitride, and silicon oxynitride.

6. Lens according to claim 1, wherein the interferential multi-layer (l) comprises a plurality of layers, preferably between 4 and 6 layers, where each layer is between 10 nm and 220 nm thick.

7. Lens according to claim 1, wherein the hardening layer (L) has a polysiloxane, acrylic, methacrylic or polyurethane base.

8. Lens according to claim 1, further comprising:
a water-repellent layer, preferably perfluorided and between 5 nm and 40 nm thick.

9. Lens according to claim 2, wherein said flexible layer and/or said second flexible layer have been produced from an organometallic monomer from a family of organometallic monomers included in the group of families made up of: the silicon family, zirconium family, titanium family and tantalum family.

10. Lens according to claim 9, wherein said flexible layer and/or said second flexible layer have been produced from an organometallic monomer from the group made up of: hexamethyldisiloxane, tetraethyl orthosilicate, titanium isopropoxide (IV), and tetrakis(dimethylamido)zirconium(IV).

11. Lens according to claim 1, wherein said interferential multi-layer and/or said first hard layer and/or said second hard layer has been made from a material from the group made up of: ZrO₂, SiO₂, Si₃N₄ y Ta₂O₅.

12. Polymeric based lens that has an abrasion resistance value greater than 20, measured in BR units according to the Bayer test.

13. Polymeric based lens that has an abrasion resistance value less than 0.35%, measured in Haze units according to the Steel Wool test at 6 kg for 10 minutes and with mesh 0000.

14. Manufacturing method of a polymeric based lens according to claim 1, comprising:
(a) forming said hardening layer, (b) forming said hard layer, (c) forming said interferential multi-layer, and (a) activating the surface of the hardening layer by high vacuum, where said stage (d) takes place before said stage (b).

15. Method according to claim 14, wherein said activation stage is carried out via a plasma activation process, at a frequency greater than 50 kHz.

16. Method according to claim 14, further comprising:
(e) forming said adherence layer less than 10 nm thick, wherein step (e) takes place after said stage (d), where said step (e) is carried out by sputtering with an inert gas, preferably argon, in presence of oxygen and with electric power greater than 1500 W producing voltages greater than 400 V, preferably with electric powers greater than 2000 W producing voltages greater than 650 V.

17. Method according to claim 14, further comprising:
forming said flexible layer, where said step (f) is before said step (b), where in said step (f) an organometallic monomer is polymerized, where in said step (f) a sputtering method and a radio frequency PeCVD method is performed simultaneously, where said sputtering uses an inert gas atmosphere, preferably argon, in presence of oxygen and with electric power greater than 1000 W producing voltages greater than 300 V, preferably with electric power greater than 1500 W producing voltages greater than 400 V, and in said PeCVD radio frequency plasma is used, an organometallic monomer is injected, the pressure is between 10⁻² and 10⁻⁵ mbar, and the power applied is between 500 W and 3000 W.

18. Method according to claim 14, wherein step (b) includes sputtering with an inert gas atmosphere, preferably argon, in presence of oxygen or nitrogen and with electric power between 500 W and 3000 W producing voltages between 300 V and 800 V.

19. Method according to claim 14, wherein step (c) includes sputtering with an inert gas atmosphere, alternatively in presence of oxygen or nitrogen and with electric power of between 500 W and 3000 W producing voltages between 300 V and 800 V.

20. Method according to claim 14, wherein step (d) includes producing a water-repellent layer, wherein step (d) takes place after said step (c).
